(19) United States
(12) Patent Application Publication
(10) Pub. No.: US 2003/0134149 A1
(43) Pub. Date: Jul. 17, 2003

(54) Transparent conductive film and electroluminescence light emitting device therewith

(75) Inventors: Takehiro Miyashita, Sodegaura-shi (JP); Yukinori Asakawa, Sodegaura-shi (JP); Akemi Nakajima, Nagoya-shi (JP); Masato Koyama, Nagoya-shi (JP); Masanori Makino, Tokyo (JP); Akira Suzuki, Sodegaura-shi (JP); Satoru Okada, Sodegaura-shi (JP)

Correspondence Address: BURNS DOANE SWECKER & MATHIS L L P, POST OFFICE BOX 1404, ALEXANDRIA, VA, 22313-1404, US

(73) Assignee: Mitsui Chemicals, Inc., Tokyo (JP)

(21) Appl. No.: 10/300,749

(22) Filed: Nov. 21, 2002

(30) Foreign Application Priority Data
Jan. 16, 2002 (JP) 2002-006854

(51) Int. Cl. H05B 33/00; B32B 9/00

(52) U.S. Cl. 428/690; 428/917; 428/702; 428/697; 313/503

(57) ABSTRACT

There is provided a transparent conductive film comprising: a substrate(A), and a transparent conductive layer(B) formed on one main surface of the substrate(A), wherein the layer(B) mainly comprises indium, tin and oxygen atoms, and a resistance variation rate of the layer(B) is 5% or less after 60% to 70% of the surface area of the layer(B) is covered with a 28 wt % aqueous ammonia solution for five hours.

### BACKGROUND OF THE INVENTION

1. Field of the Invention

This invention relates to a transparent conductive film and an electroluminescence light emitting device therewith. In particular, it relates to a transparent conductive film for an electroluminescence light emitting device exhibiting improved durability, alkali resistance, printing properties and flexibility as well as an electroluminescence light emitting device comprising the transparent conductive film as a transparent electrode and a phosphor coated with aluminum nitride conformational coating as a luminescent layer.

2. Description of the Related Art

Transparent conductive films have been used in a wide variety of applications, for example as an electrode for an input device such as a transparent touch panel; an electrode for a display device such as a liquid-crystal display, an electroluminescence display and an electrochromic display; and further as a window electrode for a photoelectric transducer such as a solar cell and an electromagnetic shielding film in an electromagnetic shield.

One of the products requiring a transparent electrode is an electroluminescence device (EL device). A known one of such devices has a structure comprising a transparent conductive layer deposited on a transparent substrate as a base where a luminescent layer and a rear electrode are sequentially deposited by printing on the transparent conductive layer. For example, the transparent conductive layer is an ITO layer which is a conductive oxide mainly comprising indium, tin and oxygen atoms; the luminescent layer is made of aluminum nitride, zinc sulfide, cadmium sulfide or zinc selenide; and the rear electrode is made of aluminum or carbon.

For forming an ITO layer on a transparent polymer film, the ITO layer must be deposited at a lower temperature than that in forming on a glass substrate because the transparent polymer film is not adequately heat resistant. Specifically, when using a glass substrate, an ITO layer can be deposited or heated after deposition, at a temperature of 400° C. or higher at which the ITO layer can be easily crystallized. A common transparent polymer film is, however, deformed or denatured at such a high temperature. An ITO layer must be, therefore, deposited on a common transparent polymer film at a low temperature of 200° C. or lower. An ITO layer deposited at such a low temperature is chemically unstable. For example, when using an ITO layer on which another organic material has been applied for preparing an EL device, the ITO layer itself may be denatured over time, leading to defects such as an altered conduction property or physical peeling. Thus, it may cause practical problems such as generation of nonluminescent parts and, if luminescent, a short luminescence life.

There has been, therefore, needed to provide a technique whereby a chemically stable ITO layer is deposited on a transparent polymer film.

JP-A 9-286070 has disclosed that an amorphous transparent conductive layer mainly comprising indium, tin and oxygen atoms is deposited on a transparent base to give a transparent conductive laminate exhibiting good moisture/heat resistance and excoriation resistance which can retain an amorphous state even after heating. An ITO layer with a specific resistance of 1×10⁻² Ω·cm or more can be deposited and then heated for reducing a specific resistance to 1×10⁻² Ω·cm or less while the layer is maintained in an amorphous state, to give a quite stable transparent electrode for an EL device.

As an electroluminescence phosphor prepared by coating of phosphor particles with aluminum nitride (JP-A 11-260557) conformational coating has been used, it has been needed to maintain luminescence durability in an EL device using the phosphor.

When using a phosphor coated with aluminum nitride conformational coating, an alkaline substance may be generated from a luminescent layer during operation under particular conditions such as a higher temperature and a higher humidity than usual. Under such conditions, not only devices using an ITO layer formed as usual but also those using an ITO layer prepared as described in JP-A 9-286070 having a low alkali resistance show insufficient durability, leading to additional problems such as generation of nonluminescent parts and a reduced luminescence life as an EL device in a practical use.

There has been found a problem that a transparent polymer film on which the ITO layer has been deposited tends to be curled due to a difference in a shrinkage rate between the transparent polymer film and the transparent conductive layer (ITO layer) during heating for stabilizing the ITO layer and thus a luminescent layer does not necessarily exhibit good printing properties.

In addition, since an EL device sometimes lights while being bent, it must be flexible. It has been, however, found that an ITO layer tends to be cracked when an internal stress in the ITO layer is higher.

### SUMMARY OF THE INVENTION

Thus, an objective of this invention is to provide a transparent conductive film with good alkali resistance which can improve durability of an EL device during lighting even when using a phosphor (electroluminescent phosphor) coated with aluminum nitride conformational coating as a phosphor in the EL device and can maintain good flatness after heating and in which a transparent conductive layer is resistant to crack forming when being bent; and an EL device therewith.

After intense attempts, we have found the followings to achieve this invention.

[1] When operating an EL device comprising a phosphor coated with aluminum nitride conformational coating as a luminescent layer under a particular environment, an alkaline substance may be generated from the luminescent layer. The alkaline substance may destroy an ITO layer, which can no longer function as an electrode, leading to reduction in a luminance, generation of nonluminescent parts and a reduced life as an EL device.

[2] An EL device formed by sequentially depositing a luminescent layer (C) made of particles containing at least phosphor and a rear electrode (D) on a conductive layer surface of a transparent conductive film in which the particles is coated with aluminum nitride conformational coating, wherein the transparent conductive film is formed by depositing a transparent conductive layer (B) mainly comprising indium, tin and oxygen atoms on one main surface of a substrate (A) and exhibits a resistance variation rate of 5% or less after 60% to 70% of the surface area of the transparent conductive layer (B) is covered with a 28 wt % aqueous ammonia solution for five hours, can exhibit extremely improved performance in practical use that over-time deterioration in a luminance during continuous lighting at a higher temperature and a higher humidity and generation of nonluminescent parts can be considerably inhibited.

[3] A transparent conductive layer (B) mainly comprising indium, tin and oxygen atoms can be formed on one main surface of a substrate (A) by sputtering under the conditions where particular amounts of oxygen and hydrogen gases are added to a sputtering gas, to provide a transparent conductive film exhibiting the above property of alkali resistance.

According to the first aspect of the present invention, there is provided a transparent conductive film comprising: a substrate(A), and a transparent conductive layer(B) formed on one main surface of the substrate(A), wherein the layer(B) mainly comprises indium, tin and oxygen atoms, and a resistance variation rate of the layer(B) is 5% or less after 60% to 70% of the surface area of the layer(B) is covered with a 28 wt % aqueous ammonia solution for five hours.

According to the second aspect of the present invention, there is provided the transparent conductive film according to the first aspect of the present invention, wherein the transparent conductive layer is formed by sputtering using an indium-tin oxide target under a gaseous atmosphere containing 5 vol % to 40 vol % of oxygen and 1 vol % to 10 vol % both inclusive of hydrogen to a sputtering gas.

According to the third aspect of the present invention, there is provided the transparent conductive film according to the first aspect of the present invention, wherein the transparent conductive layer is formed by sputtering using an indium-tin alloy target under a gaseous atmosphere containing 30 vol % to 100 vol % of oxygen and 1 vol % to 10 vol % of hydrogen to a sputtering gas.

According to the fourth aspect of the present invention, there is provided the transparent conductive film according to any of the first to third aspect of the present invention, wherein the transparent conductive layer is further heated at a temperature in a range of 80° C. to 180° C.

According to the fifth aspect of the present invention, there is provided the transparent conductive film according to any of the first to fourth aspect of the present invention, wherein the transparent conductive layer is amorphous.

According to the sixth aspect of the present invention, there is provided an electroluminescence light emitting device comprising: the transparent conductive film with the transparent conductive layer (B) according to any of the first to fifth aspect of the present invention, a luminescent layer(C) comprises particles at least containing phosphor coated with aluminum nitride conformational coating, and a rear electrode(D), wherein the layer(C) and layer(D) are sequentially formed in this order on the layer(B) of the transparent conductive film.

This invention can provide a transparent conductive film with significantly improved alkali resistance, flatness after heating and flexibility by adding hydrogen under a high oxygen-concentration atmosphere during depositing a transparent conductive layer mainly comprising indium, tin and oxygen atoms. Furthermore, the film can be used as a transparent electrode for an electroluminescence light emitting device to provide a highly durable electroluminescence light emitting device because deterioration in a luminance during continuous lighting at a higher temperature and a higher humidity than usual can be prevented particularly when using a phosphor coated with aluminum nitride conformational coating as a luminescent layer.

### BRIEF DESCRIPTION OF THE DRAWINGS

FIG. 1 is a cross section of a transparent conductive film.

FIG. 2 is a cross section of an electroluminescence light emitting device.

FIG. 3 is an illustrative view of a sample for testing alkali resistance.

### DETAILED DESCRIPTION OF PREFERRED EMBODIMENTS

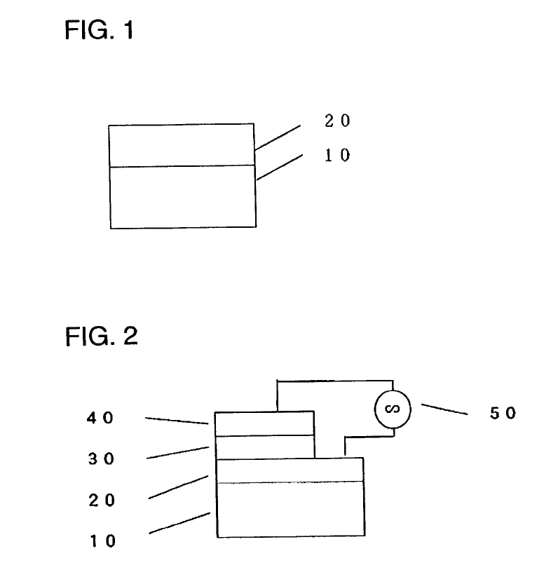

A transparent conductive film according to the present invention comprises a transparent conductive layer 20 of an oxide mainly comprising indium, tin and oxygen atoms (ITO) on a base 10 made of at least a transparent polymer 10 as shown in FIG. 1.

The substrate (A) as a main component of the base may be preferably any transparent polymer film as long as it is transparent within a visible region; specifically, polyethylene terephthalate, polyether sulfone, polystyrene, polyethylene, polyethylene naphthalate, polyarylates, polyether ether ketones, polycarbonates, polypropylene, polyimides and triacetylcellulose. The film preferably has a thickness of 10 μm to 250 μm. A film thickness of 10 μm or less may give a base with inadequate mechanical strength while a thickness of 250 μm or more may give a film with deteriorated flexibility so that it cannot be suitably wound by a roll for use.

Among the above materials for a transparent polymer film, polyethylene terephthalate is more suitably used because of its good transparency and processability. Polyether sulfone is so heat resistant that it can be more suitably used when heating is required during assembling an electroluminescence light emitting device (EL device).

The surface of such a transparent polymer film can be pretreated for improving adhesiveness of a transparent conductive layer made of an ITO formed thereon to the base, for example, by sputtering, glow discharge, corona discharge, treatment with plasma or ions using, e.g., a plasma gun, flame treatment, etching such as ultra violet or electron beam irradiation and undercoating. The film may be, if necessary, cleaned by washing with a solvent or ultrasonic cleaning before depositing a transparent conductive layer made of an ITO.

A conductive layer (B) of a transparent conductive film according to the present invention is a transparent conductive layer of an oxide mainly comprising indium, tin and oxygen (ITO), and its resistance variation rate is 5% or less after 60% to 70% of the surface area of the transparent conductive layer is covered with a 28 wt % aqueous ammonia solution for five hours.

When using a phosphor coated with aluminum nitride conformational coating as a luminescent layer, an alkali substance may be generated from the luminescent layer under particular conditions such as a higher temperature and a higher humidity than usual. Such an alkali substance may destroy the ITO layer to a degree that it can no longer function as an electrode, leading to a reduction in a luminance and generation of nonluminescent parts and thus to a reduced life of the EL device. Therefore, in an EL device using a phosphor coated with aluminum nitride conformational coating as a luminescent layer, the ITO layer constituting a transparent conductive layer is needed to have particularly good alkali resistance.

Alkali resistance of a transparent conductive layer may be evaluated by, for example, covering 60% to 70% of the surface area of the transparent conductive layer with a 28 wt % aqueous ammonia solution for five hours and determining a resistance variation rate before and after covering with the aqueous ammonia solution. When the resistance variation rate is within 5%, a phosphor coated with aluminum nitride conformational coating can be used as a luminescent layer to prevent a luminance of an EL device produced from being deteriorated over time or prevent nonluminescent parts from generating during continuous lighting at a higher temperature and a higher humidity than usual.

The above ITO layer exhibiting alkali resistance may be deposited by sputtering where an inert gas such as argon is used as a sputtering gas under a high oxygen-concentration atmosphere further containing hydrogen gas.

A specific sputtering method may be appropriately selected from, but not limited to, direct current (DC) sputtering, alternate current (RF) sputtering, direct current (DC) magnetron sputtering, alternate current (RF) magnetron sputtering and other alternate current magnetron sputtering methods, ECR sputtering, dual magnetron sputtering. DC magnetron sputtering or RF magnetron sputtering is preferably employed because a deposition rate and an ITO layer can be adequately controlled. DC magnetron sputtering is particularly preferable because of its simple equipment configuration.

A pressure during sputtering is preferably 13.3 mPa to 2600 mPa, more preferably 13.3 mPa to 1330 mPa, further preferably 26.6 mPa to 266 mPa. A base temperature during deposition is preferably 5° C. to 150° C., more preferably 10° C. to 150° C., further preferably 20° C. to 150° C., particularly preferably 20° C. to 100° C.

Sputtering under a high oxygen-concentration atmosphere herein means sputtering under an oxygen partial pressure rate higher than an oxygen partial pressure rate to a sputtering gas (an inert gas such as argon) where an electrical resistivity of an ITO layer immediately after deposition is minimum. Deposition using such a technique may give a stable ITO layer with reduced structural defects such as oxygen defects. In the present invention, sputtering is conducted under an atmosphere further containing hydrogen.

An oxygen partial pressure rate described above where an electric resistivity of an ITO layer is minimum depends on deposition conditions such as the type, a density and an indium/tin ratio of a target used, a base temperature and a deposition rate, and can be experimentally determined.

An amount of oxygen gas expressed by a volume rate to a sputtering gas (partial pressure rate) is preferably 5% to 40%, more preferably 5% to 25%, further preferably 5% to 20%, particularly preferably 10% to 20% when a target is an indium-tin oxide. When a target is an indium-tin alloy, it is preferably 30% to 100%, more preferably 40% to 100%, further preferably 50% to 100%, particularly preferably 60% to 100%.

In the present invention, an ITO layer as a transparent conductive layer is deposited by sputtering using a sputtering gas to which, in addition to oxygen, hydrogen is added.

Although it is not clearly understood why alkali resistance in an ITO layer is improved by adding oxygen and further hydrogen gas as a reactive gas to a sputtering gas, it is supposed that the ITO layer would incorporate hydrogen to improve reduction resistance, resulting in significant improvement in resistance to an alkali as a reducing agent.

The amount of hydrogen is preferably 1% to 10%, more preferably 2% to 5%, further preferably 2% to 4% as a volume rate to a sputtering gas (an inert gas such as argon) (partial pressure rate). A hydrogen amount of less than 1% tends to render reduction resistance, i.e., alkali resistance lower due to inadequate incorporation of hydrogen. If a hydrogen amount is more than 10%, an ITO layer becomes chemically unstable due to excessive incorporation of reducing hydrogen into the layer so that the ITO layer itself may be denatured over time by a corrosive chemical substance applied during producing an EL device, leading to tendency to deteriorated durability.

By adding an appropriate amount of hydrogen gas to a sputtering gas, a proper amount of hydrogen can be incorporated into the ITO layer so that an internal stress in the ITO layer may be reduced, flatness after heating may be improved and the ITO layer may become more flexible, resulting in improvement in processability during production of an EL device and in flexibility after producing the EL device.

A target in sputtering may be an indium-tin alloy or indium oxide-tin oxide (indium-tin oxide), preferably a sintered indium oxide-tin oxide.

A content of tin to indium in a target is preferably 3 to 50 wt %. Presence of an appropriate amount of tin can cause carrier electrons to be generated in an ITO layer adequately to reduce a specific resistance. An excessive content of tin may lead to an excessively higher specific resistance immediately after deposition, which tends to be little reduced by heating. An excessively small content of tin tends to deteriorated durability of an ITO layer. Thus, a content of tin to indium is more preferably 10 to 50 wt %, further preferably 15 to 50 wt %. It is preferable that a content of impurities are is as small as possible, but an impurity such as silicon may be contained up to 1%.

A thickness of ITO layer is preferably 50 to 300 nm, more preferably 70 to 200 nm when being used as an EL device. If it is less than 50 nm, the EL device may be less durable while if it is more than 300 nm, the device may be less flexible.

A specific resistance of an ITO layer formed under the above conditions where oxygen and hydrogen are added to a sputtering gas is as high as 1×10⁻² Ω·cm or more. It generally has a sheet resistance of 2500 Ω/□ or more, depending on a thickness of the ITO layer. When being used as a transparent conductive film for an EL device, the film must have a sheet resistance of 500 Ω/□ or less, which can be reduced by one order by heating the transparent conductive film prepared. Thus, a transparent conductive film with a sheet resistance of 500 Ω/□ or less can be provided.

Heating can be conducted under any conditions as long as a base and an ITO layer remain stable after heating. It may be achieved by heating the product at a temperature over room temperature for a given period. A preferable heating temperature is 80 to 180° C. If a heating temperature is lower than 80° C., an electron density may not be effectively increased. Thus, it may take a long period, for example, several days, to achieve desired effect of heating treatment. A heating temperature of higher than 180° C. may cause problems such as deformation of a polymer film. Heating at a temperature in the range of 80 to 180° C. may be applicable to most of transparent polymer films.

Any atmosphere may be employed during heating as long as it is not strongly oxidative; for example, heating may be conducted in vacua, in the air or in an inert gas such as nitrogen. A heating period depends on various factors such as the type and a thickness of a base, a specific resistance and a thickness of an ITO layer and a heating temperature, and may be experimentally determined. It is preferably about 10 min to 24 hours.

An ITO layer in this invention may be partially crystallized, but preferably has an amorphous region. More preferably, it is amorphous without a crystalline region. The reason why the alkali-resistance of the ITO layer is improved when the ITO layer is amorphous is not clear. However, it is reasonable to suppose that one of the reasons is that there is no grain boundary in the amorphous ITO layer. When the ITO layer is crystalline, an alkali-component can reach to an interface between the ITO layer and the base via grain boundaries in the ITO layer. Therefore, it is likely that this easily causes the ITO layer exfoliation from the base or the ITO layer is liable to be dissolved by alkali-components in the grain boundaries.

An amorphous ITO layer as used herein refers to an ITO layer which does not exhibit an In₂O₃ (222) peak with 2θ=30° to 31° and an In₂O₃ (400) peak with 2θ=35° to 36° indicating a crystalline material in a X-ray diffraction pattern by a θ-2θ method using CuKα X-ray.

As long as transparency is not lost, a metal thin layer with a certain thickness may be formed for increasing adhesion between a transparent polymer film and a transparent conductive layer. Since the metal thin layer is in contact with the ITO layer, a substantial part of the metal thin layer has been practically converted to a metal oxide, but desired effect may be achieved. Examples of a metal material which can be used include nickel, chromium, gold, silver, zinc, zirconium, titanium, tungsten, tin, vanadium and alloys made of two or more thereof. The metal thin layer may have any thickness as long as transparency is not significantly lost, and the thickness is preferably about 0.02 nm to 10 nm. If the thickness is too small, adhesion is not sufficiently improved. On the other hand, if it is too large, transparency may be lost. The metal thin layer may be formed by a known process for forming a layer; suitably sputtering and vacuum deposition. Among others, sputtering is suitably employed for forming a transparent conductive layer deposited after forming the metal thin layer. Thus, these two layers can be deposited using the same apparatus, resulting in improvement in a production efficiency.

A transparent hard coat layer may be formed on the opposite surface in the base to the surface on which the ITO layer is formed for improving mechanical strength. Furthermore, an appropriate protective layer may be deposited on the ITO layer as long as it does not deteriorate an electric conductivity, transparency, environment resistance and durability as a transparent electrode. An appropriate film layer other than a metal thin layer between a base made of a transparent polymer film and a transparent conductive layer may be inserted for improving transparency and for preventing emission of a gas or precipitation of a component.

An EL device according to the present invention will be described with reference to FIG. 2.

An EL device according to the present invention has a configuration where on one main surface of a transparent polymer film (A) 10, are deposited a transparent conductive layer (B) 20 made of an oxide mainly comprising indium, tin and oxygen (ITO) to form a transparent conductive layer with good alkali resistance; a luminescent layer (C) containing phosphor particles, particularly preferably a luminescent layer (C) 30 containing a phosphor coated with aluminum nitride conformational coating; and a rear electrode (D) 40 in the sequence of ABCD. A voltage may be applied by a power source 50 between the transparent conductive layer (B) 20 and the rear electrode (D) 40 to initiate light emission, i.e., operation as an EL device.

There are no particular restrictions to a material for a luminescent layer (a phosphor). An appropriate material which can emit luminescence by a voltage applied can be used as the phosphor. A material for the phosphor may be appropriately selected from metal sulfides such as zinc sulfide, cadmium sulfide, strontium sulfide, calcium sulfide, calcium-gallium sulfide and strontium-gallium sulfide, and metal selenides such as zinc selenide. A material for the phosphor is preferably zinc sulfide, especially a zinc sulfide containing a proper element. The type of the element can be appropriately chosen to change a luminescent color; for example, copper may alter a luminescent color to green while manganese may alter it to yellow. Zinc sulfide is generally a powder, size of which may be about 20 μm to 30 μm. The phosphor coated with aluminum nitride conformational coating is preferable because it may improve retention of a luminance at a higher temperature and a higher humidity than usual. This coating means a coating to an outer surface of individual phosphor particle. The coating is continuous and is of a non-particulate nature. Conformational means that a sub-micron feature of the phosphor particle under the high resolution scanning electron microscopy is replicated.

When using the phosphor coated with aluminum nitride conformational coating, an alkali substance may be generated from a luminescent layer during operation of the EL device under the specific conditions, leading to a reduced luminance and generation of nonluminescent parts during lighting at a higher temperature and a higher humidity than usual. A transparent conductive film with improved alkali resistance according to the present invention may be, however, used to prevent a practical life as an EL device from being reduced due to these defects.

There are no particular restrictions to a method of forming a luminescent layer. Application method, for example, may be used as the method. Specifically, a luminescent layer can be formed by blending a powdery luminescent material containing a phosphor with an appropriate binder, dispersing the mixture in an appropriate solvent, applying the dispersion on a transparent conductive layer and then heated the product at 100 to 150° C. to evaporate the solvent. Examples of a binder which can be suitably used include cyanoethylcellulose, cyanoethylpullulan and cyanoethylpolyvinyl alcohol. A solvent which can be suitably used may be any solvent which can be evaporated by heating at 100 to 150° C.; for example, but not limited to, acetone and propylene carbonate.

There are no particular restrictions to a thickness of a luminescent layer as long as it can provide a luminance adequate to a specific application. However, since an excessively thin luminescent layer provides an inadequate luminance, its thickness is preferably 50 μm or more. When forming a luminescent layer, an electrode for operating an EL device must be taken from a transparent conductive layer. Thus, a space for an electrode terminal must be left by, for example, not forming a luminescent layer at the end.

After forming the luminescent layer, a rear electrode is formed on the luminescent layer. For improving a luminance, a dielectric layer may be formed between the luminescent layer and the rear electrode. The dielectric layer may be formed by physical or chemical vapor deposition of a material with a higher dielectric constant, but can be conveniently formed by an application method as described for forming a luminescent layer. In an application method, a dielectric layer may be formed by blending a powdery material with a higher dielectric constant such as barium titanate with a binder, dispersing the mixture in a solvent and using the dispersion for deposition as described for forming a luminescent layer. A binder and a solvent which can be suitably used for forming a dielectric layer may be selected from those which can be used for forming a luminescent layer.

Finally, a rear electrode for applying a voltage to the luminescent layer is formed. The rear electrode may be made of any conductive material without limitations; for example, metals such as aluminum and silver and carbon can be suitably used. Silver and carbon are particularly preferable because their pastes are commercially available and can be used in an application method to form a rear electrode.

For lighting the electroluminescent plane lamp thus prepared, a voltage must be applied between the transparent conductive layer and the rear electrode. An applied voltage is preferably an alternating voltage of an alternate current without a direct current component. If a direct current component is contained, a one-directional current flows within the electroluminescent plane lamp, leading to accelerated deterioration of the transparent conductive layer. An alternate-current power supply may have any voltage or frequency as long as the plane lamp can light. An alternating voltage of 100 V (effective voltage) and about 400 Hz may be used to initiate light emission. An inverter power supply capable of supplying an alternating voltage with such a frequency is disclosed in, for example, JP-A 2-257591.

### EXAMPLES

This invention will be more specifically described with reference to Examples.

The following (1) to (3) are procedures for evaluating alkali resistance, flatness and flexibility of a transparent conductive film prepared in Examples and Comparative Examples, respectively.

In (4), there is described a lightening test using an EL device in which a transparent electrode is a transparent conductive film prepared in one of Examples and Comparative Examples and a luminescent layer is made of a phosphor coated with aluminum nitride conformational coating.

(1) Alkali Resistance Test

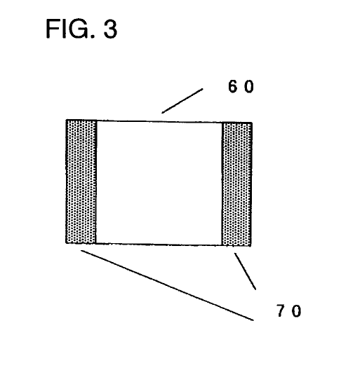

A transparent conductive film prepared in one of Examples and Comparative Examples is cut into 7 cm width×5 cm sample pieces, at whose ends electrodes 70 from a silver paste with a width of 1 cm are formed while leaving a 5 cm square of the ITO surface 60 as illustrated in FIG. 3. Such a sample is determined for an inter-electrode resistance (R₀). To the sample is added dropwise 0.5 mL of a 28 wt % aqueous ammonia solution in an atmosphere of 23° C. and 50% RH, and then a 4 cm square cover is placed on the sample to cover 16 cm² of the 25 cm² ITO layer with the aqueous ammonia solution. After leaving for 5 hours, an inter-electrode resistance (R) is measured and a resistance variation rate X (%) is determined in accordance with the following equation.

X=(R−R₀)/R₀×100(%)

(2) Flatness Test

A transparent conductive film prepared in one of examples and comparative examples is cut into 10 cm square samples. A sample is heated at a given temperature for a given period as described in one of Examples and Comparative Examples. The sample is placed on a horizontal surface such that its conductive surface is lower, and then an average of the heights of the four corners (mm) is determined.

(3) Flexibility Test

A transparent conductive film prepared in one of Examples and Comparative Examples is cut into 10 cm square samples. A sample is bent 10 times at the same part to an angle of 180° around a cylinder with a diameter of 35 mm while keeping a conductive surface inside. A central 1 cm square area is magnified by a microscope and the number of defects generated is counted.

(4) Lighting Test of an EL Device at a Higher Temperature and a Higher Humidity than Usual

On a transparent conductive layer of a transparent conductive film prepared in one of Examples and Comparative Examples were sequentially formed a luminescent layer made of Zinc Sulfide as a phosphor coated with aluminum nitride conformational coating and a dielectric layer by an application method. Heating for evaporating a solvent after application was conducted by drying the product in the air at 120° C. for 12 hours. During forming the luminescent layer and the dielectric layer, a part of the transparent conductive layer is kept untreated for an electrode terminal. Finally, a carbon paste is applied on the dielectric layer and dried to form a rear electrode. Thus, an electroluminescent plane lamp is provided.

Under an atmosphere of a temperature of 60° C. and a humidity of 90% RH, an alternate current voltage of 100 V, 400 Hz without a direct current component is applied between the transparent conductive layer and the rear electrode by a power source connected with them. In that way, the voltage is applied to initiate light emission for a durability test for 150 hours.

The sample is evaluated for sizes and the number of nonluminescent parts generated.

### Example 1

On one main surface of a polyethylene terephthalate film (thickness: 125 μm) was deposited by magnetron DC sputtering an ITO layer to a thickness of 100 nm to provide a transparent conductive film. During the process, a target was a sintered indium oxide-tin oxide (composition ratio (by weight): In₂O₃:SnO₂=80:20). A sputtering gas was argon, to which were added oxygen as a reactive gas (total pressure: 266 mPa, oxygen partial pressure: 13.3 mPa) and further hydrogen to a volume ratio of 8% to the argon. After deposition of the ITO layer, the film was heated at 120° C. for 24 hours.

### Example 2

A transparent conductive film was prepared as described in Example 1, except that an ITO layer was formed using argon as a sputtering gas, to which were added oxygen as a reactive gas (total pressure: 266 mPa, oxygen partial pressure: 36.6 mPa) and further hydrogen to a volume ratio of 3% to the argon.

### Example 3

A transparent conductive film was prepared as described in Example 1, except that an ITO layer was formed using argon as a sputtering gas, to which were added oxygen as a reactive gas (total pressure: 266 mPa, oxygen partial pressure: 44.0 mPa) and further hydrogen to a volume ratio of 3% to the argon.

### Example 4

On one main surface of a polyethylene terephthalate film (thickness: 188 μm) was deposited by magnetron DC sputtering an ITO layer to a thickness of 50 nm to provide a transparent conductive film. During the process, a target was a sintered indium oxide-tin oxide (composition ratio (by weight): In₂O₃:SnO₂=80:20). A sputtering gas was argon, to which were added oxygen as a reactive gas (total pressure: 266 mPa, oxygen partial pressure: 26.6 mPa) and further hydrogen to a volume ratio of 3% to the argon. After deposition of the ITO layer, the film was heated at 150° C. for 4 hours.

### Example 5

A transparent conductive film was prepared as described in Example 1, except that before forming an ITO layer, a nickel-chromium alloy film layer (ratio by weight: 50:50) was formed to a thickness of 0.05 nm by sputtering.

### Example 6

On one main surface of a polyethylene terephthalate film (thickness: 125 μm) was deposited by magnetron DC sputtering an ITO layer to a thickness of 100 nm to provide a transparent conductive film. During the process, a target was an indium-tin alloy (composition ratio (by weight): In:Sn=80:20). A sputtering gas was argon, to which were added oxygen as a reactive gas (total pressure: 266 mPa, oxygen partial pressure: 105 mPa) and further hydrogen to a volume ratio of 4% to argon. After deposition of the ITO layer, the film was heated at 120° C. for 24 hours.

### Comparative Example 1

A transparent conductive film was prepared as described in Example 1, except that a hydrogen content was 0%.

### Comparative Example 2

A transparent conductive film was prepared as described in Example 1, except that an oxygen content was 0%.

### Comparative Example 3

A transparent conductive film was prepared as described in Example 2, except that an oxygen content was 0%.

### Comparative Example 4

A transparent conductive film was prepared as described in Example 2, except that a hydrogen content was 20%.

### Comparative Example 5

A transparent conductive film was prepared as described in Example 2, except that a hydrogen content was 0%.

### Comparative Example 6

A transparent conductive film was prepared as described in Example 6, except that a hydrogen content was 0%.

For these transparent conductive films thus prepared, an alkali resistance test, a flatness test, a flexibility test and a lighting test for an EL device at a higher temperature and a higher humidity than usual. The results are shown in Table 1. As seen from Table 1, a transparent conductive film prepared by sputtering in a high oxygen-concentration atmosphere to which an appropriate amount of hydrogen has been added shows improved alkali resistance, flatness and flexibility. An EL device with the film shows significantly improved durability at a higher temperature and a higher humidity than usual.

TABLE 1

| | | | | | | EL device properties · | |
|---|---|---|---|---|---|---|---|
| | | | | | | Lighting test | |
| | | | | | | at higher temperature | |
| | | | | | | and higher humidity | |
| | Deposition | | | | Alkali | than usual | |
| | conditions | | Physical properties | | resistance | Number of | |
| | Gas content | | | Flexibility | Resistance | nonluminescent | |
| | (%) | | Flatness | (Number of | variation | parts | |
| | Oxygen | Hydrogen | (mm) | defects) | rate (%) | φ ≧ 0.3 mm | φ < 0.3 mm |
| Exam. 1 | 5.3 | 8 | 1 | 7 | 3 | 0 | 1 |
| Exam. 2 | 16 | 3 | 5 | 22 | 0 | 0 | 0 |
| Exam. 3 | 20 | 3 | 6 | 25 | 0 | 0 | 0 |
| Exam. 4 | 11 | 3 | 2 | 20 | 5 | 0 | 2 |
| Exam. 5 | 5.3 | 8 | 1 | 5 | 1 | 0 | 0 |
| Exam. 6 | 65 | 4 | 7 | 18 | 2 | 0 | 1 |
| Comp. Exam. 1 | 5.3 | 0 | 30 | 100 | 12 | 3 | 7 |
| Comp. Exam. 2 | 0 | 8 | 1 | 4 | 38 | 6 | 15 |
| Comp. Exam. 3 | 0 | 3 | 2 | 10 | 50 | 11 | 25 |
| Comp. Exam. 4 | 16 | 20 | 3 | 15 | 25 | 5 | 13 |
| Comp. Exam. 5 | 16 | 0 | 35 | 150 | 7 | 4 | 10 |
| Comp. Exam. 6 | 65 | 0 | 35 | 118 | 15 | 4 | 7 |

What is claimed is:

1. A transparent conductive film comprising:
a substrate(A), and
a transparent conductive layer(B) formed on one main surface of the substrate(A), wherein
the layer(B) mainly comprises indium, tin and oxygen atoms, and
a resistance variation rate of the layer(B) is 5% or less after 60% to 70% of the surface area of the layer(B) is covered with a 28 wt % aqueous ammonia solution for five hours.

2. The transparent conductive film according to claim 1, wherein the transparent conductive layer is formed by sputtering using an indium-tin oxide target under a gaseous atmosphere containing 5 vol % to 40 vol % of oxygen and 1 vol % to 10 vol % of hydrogen to a sputtering gas.

3. The transparent conductive film according to claim 1, wherein the transparent conductive layer is formed by sputtering using an indium-tin alloy target under a gaseous atmosphere containing 30 vol % to 100 vol % of oxygen and 1 vol % to 10 vol % of hydrogen to a sputtering gas.

4. The transparent conductive film according to claim 1, wherein the transparent conductive layer is further heated at a temperature in a range of 80° C. to 180° C.

5. The transparent conductive film according to claim 1, wherein the transparent conductive layer is amorphous.

6. An electroluminescence light emitting device comprising:
the transparent conductive film with the transparent conductive layer (B) according to claim 1, a luminescent layer(C) comprises particles at least containing phosphor coated with aluminum nitride conformational coating, and
a rear electrode(D), wherein
the layer(C) and layer(D) are sequentially formed in this order on the layer(B) of the transparent conductive film.
